(19) United States
(12) Patent Application Publication
(10) Pub. No.: US 2014/0077254 A1
(43) Pub. Date: Mar. 20, 2014

(54) SEMICONDUCTOR DEVICE AND METHOD OF MANUFACTURING SAME

(71) Applicant: KABUSHIKI KAISHA TOSHIBA, Tokyo (JP)

(72) Inventors: Masaru IZUMISAWA, Himeji-shi (JP); Syotaro ONO, Tatsuno-shi (JP); Hiroshi OHTA, Himeji-shi (JP); Hiroaki YAMASHITA, Himeji-shi (JP)

(73) Assignee: KABUSHIKI KAISHA TOSHIBA, Tokyo (JP)

(21) Appl. No.: 13/780,246

(22) Filed: Feb. 28, 2013

(30) Foreign Application Priority Data
Sep. 19, 2012 (JP) 2012-206195

(51) Int. Cl. H01L 29/06; H01L 21/48; H01L 29/739

(52) U.S. Cl. CPC H01L 29/0607; H01L 29/7393; H01L 21/4814
USPC 257/139; 257/622; 438/666

(57) ABSTRACT

A semiconductor device includes an element region and an end region, the element region having a semiconductor element formed therein, and the end region surrounding the element region. The semiconductor device includes a semiconductor substrate, a trench, an insulating layer, and a field plate conductive layer. The trench is formed in the semiconductor substrate so as to surround the element region in the end region. The field plate conductive layer is formed in the trench via the insulating layer.

### CROSS-REFERENCE TO RELATED APPLICATIONS

This application is based upon and claims the benefit of priority from the prior Japanese Patent Application No. 2012-206195, filed on Sep. 19, 2012, the entire contents of which are incorporated herein by reference.

### FIELD

Embodiments relate to a semiconductor device and a method of manufacturing the same.

### BACKGROUND

In an end region surrounding an element region where semiconductor elements are formed, various structures for relieving electric field concentration and thereby maintaining voltage withstand are used. One known example of such a structure is a resistive field plate (RFP) structure. However, a conventional resistive field plate structure has variation in shape and is of large size.

### BRIEF DESCRIPTION OF THE DRAWINGS

FIG. 1 is a top view showing a semiconductor device according to an embodiment.

FIG. 2A is a cross-sectional view taken along the line A-A′ of FIG. 1.

FIG. 2B is a top view showing a semiconductor device according to another embodiment.

FIGS. 3A-3C are cross-sectional views showing manufacturing processes of an end region 20 according to the embodiment.

FIG. 4 is a cross-sectional view showing a semiconductor device according to a comparative example.

### DETAILED DESCRIPTION

A semiconductor device according to an embodiment includes an element region and an end region, the element region having a semiconductor element formed therein, and the end region surrounding the element region. The semiconductor device includes a semiconductor substrate, a trench, an insulating layer, and a field plate conductive layer. The trench is formed in the semiconductor substrate so as to surround the element region in the end region. The field plate conductive layer is formed in the trench via the insulating layer.

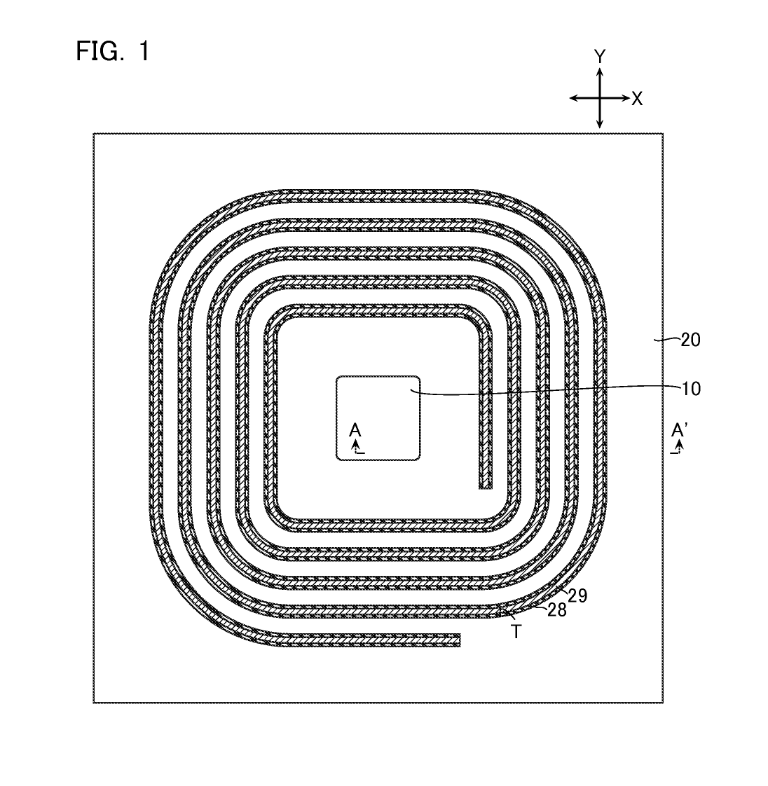

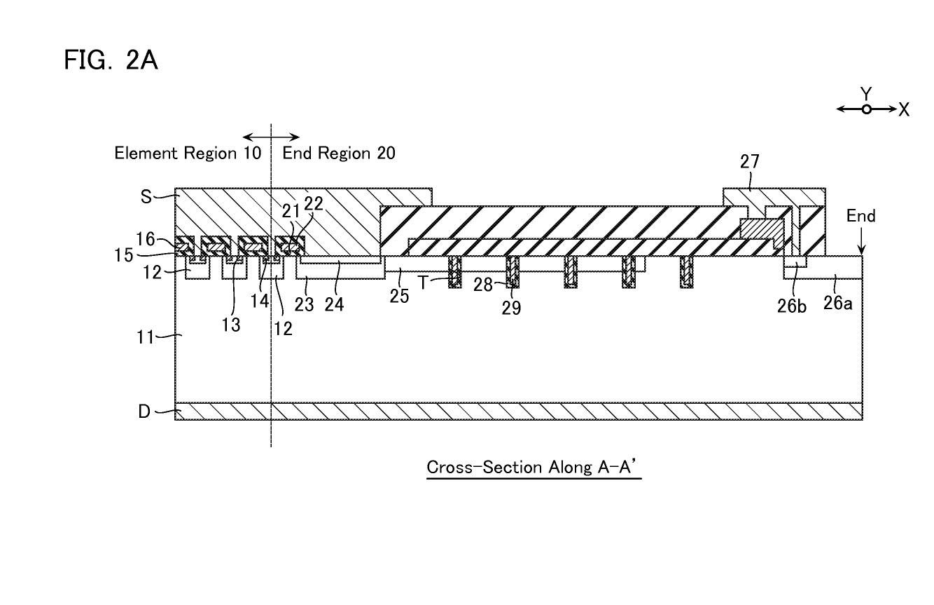

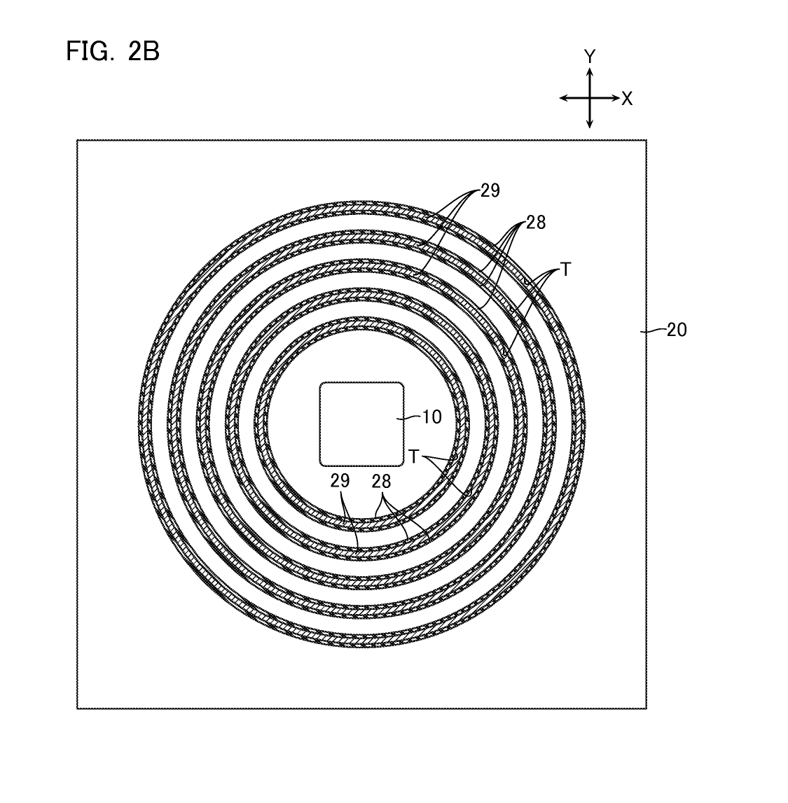

A semiconductor device according to an embodiment is described below with reference to FIGS. 1 and 2A. FIG. 1 is a top view showing the semiconductor device according to the embodiment, and FIG. 2A is a cross-sectional view taken along the line A-A′ of FIG. 1. Note that FIG. 1 shows only an element region 10, an end region 20, a trench T, an insulating layer 28, and a field plate conductive layer 29 to be mentioned later. Other configurations are omitted from FIG. 1.

As shown in FIG. 1, the semiconductor device according to the embodiment is configured by: the element region 10 having a semiconductor element (for example, vertical type power MOSFET) formed therein; and the end region 20 surrounding the element region 10 and having a resistive field plate structure formed therein. Note that as an example, a boundary between the element region 10 and the end region 20 in the embodiment is assumed to be a center of a later-mentioned p type base layer 12 positioned closest to an edge (FIG. 2A).

Next, the element region 10 is described in detail. As shown in FIG. 2A, the element region 10 includes, within an n type semiconductor substrate 11: a p type base layer 12, a p+ type contact layer 13, and an n type source diffusion layer 14 that are formed in stripes extending in a Y direction (direction perpendicular to a plane of paper in FIG. 2A) and having a certain pitch in an X direction. The n type semiconductor substrate 11 functions as a drain diffusion region of the MOSFET, and the p type base layer 12 functions as a channel of the MOSFET. The p+ type contact layer 13 functions as a contact connected to a source diffusion region of the MOSFET, and the n type source diffusion layer 14 functions as the source diffusion region of the MOSFET. Note that in the present specification, “p+” indicates an impurity concentration higher than “p”.

The p type base layer 12 is formed in a surface of the n type semiconductor substrate 11. The p+ type contact layer 13 is formed in a surface of the p type base layer 12. The n type source diffusion layer 14 is formed in a surface of the p+ type contact layer 13.

As shown in FIG. 2A, the element region 10 includes a gate electrode 16 on the n type semiconductor substrate 11, via a gate insulating film 15. The gate insulating film 15 functions as a gate insulating film of the MOSFET, and the gate electrode 16 functions as a gate electrode of the MOSFET. The gate electrodes 16 are formed in stripes extending in the Y direction and having a certain pitch in the X direction. The gate electrode 16 is formed commonly to adjacent two p type base layers 12.

As shown in FIG. 2A, the element region 10 includes a source electrode S and a drain electrode D that function respectively as a source and a drain of the MOSFET. The source electrode S contacts an upper surface of the p+ type contact layer 13 and an upper surface of the n type source diffusion layer 14. The drain electrode D contacts an underside surface of the n type semiconductor substrate 11.

Next, the end region 20 is described in detail. As shown in FIG. 2A, the end region 20 includes a gate insulating film 21 and a gate electrode 22, in a vicinity of the boundary with the element region 10. These gate insulating film 21 and gate electrode 22 have shapes similar to those of the gate insulating film 15 and the gate electrode 16 in the element region 10.

As shown in FIG. 2A, the end region 20 includes, on a further outwardly peripheral side than the gate electrode 22: a p type guard ring layer 23, a p+ type guard ring layer 24, and a p− type guard ring layer 25. Note that in the present specification, “p−” indicates an impurity concentration lower than “p”.

The p type guard ring layer 23 is formed in a surface of the n type semiconductor substrate 11. The p+ type guard ring layer 24 is formed in a surface of the p type guard ring layer 23. The p− type guard ring layer 25 is formed in a surface of the n type semiconductor substrate 11, and is adjacent to the p type guard ring layer 23 and the p+ type guard ring layer 24. The p+ type guard ring layer 24 is electrically connected to the source electrode S. These guard ring layers 2325 are formed circularly surrounding the element region 10 and relieve electric field concentration.

As shown in FIG. 2A, the end region 20 includes, at an end of the n type semiconductor substrate 11: a p type field stop layer 26a, an n type field stop layer 26b, and a field stop electrode 27. The p type field stop layer 26a is formed in a surface of the n type semiconductor substrate 11. The n type field stop layer 26b is formed in a surface of the p type field stop layer 26a. The field stop electrode 27 contacts an upper surface of the n type field stop layer 26b. An electric field formed by applying a voltage from the above-described field stop electrode 27 to the p type field stop layer 26a and n type field stop layer 26b makes it possible to prevent a depletion layer from extending to the end of the n type semiconductor substrate 11.

As shown in FIG. 2A, the end region 20 includes the trench T, the insulating layer 28, and the field plate conductive layer 29. The trench T is formed digging out the n type semiconductor substrate 11 as shown in FIG. 2A, and is formed spirally surrounding the element region 10 as shown in FIG. 1. Note that a spiral form is just one example. As shown in FIG. 2B, the trench T may be formed concentrically. A depth of the trench T is, for example, deeper than a lower end of the p type base layer 12, that is, the depth of the trench T is 2 μm˜6 μm. Moreover, a width of the trench T is, for example, narrower than a width of the p type base layer 12, that is, the width of the trench T is 0.4 μm˜2.0 μm.

The insulating layer 28 is formed on an inner wall of the trench T. For example, the insulating layer 28 is configured by silicon oxide (SiO₂) and has a thickness of 0.05 μm˜0.20 μm. The field plate conductive layer 29 fills the trench T via the insulating layer 28. That is, the field plate conductive layer 29 is formed spirally surrounding the element region 10. Note that a spiral form is just one example. As shown in FIG. 2B, the field plate conductive layer 29 may be formed concentrically to match the shape of the trench T. For example, the field plate conductive layer 29 is configured by any of polysilicon and a metal material such as aluminum or the like.

Applying a voltage to the above-described field plate conductive layer 29 enables concentration of electric field in a surface of the n type semiconductor substrate 11 in the end region 20 to be relieved.

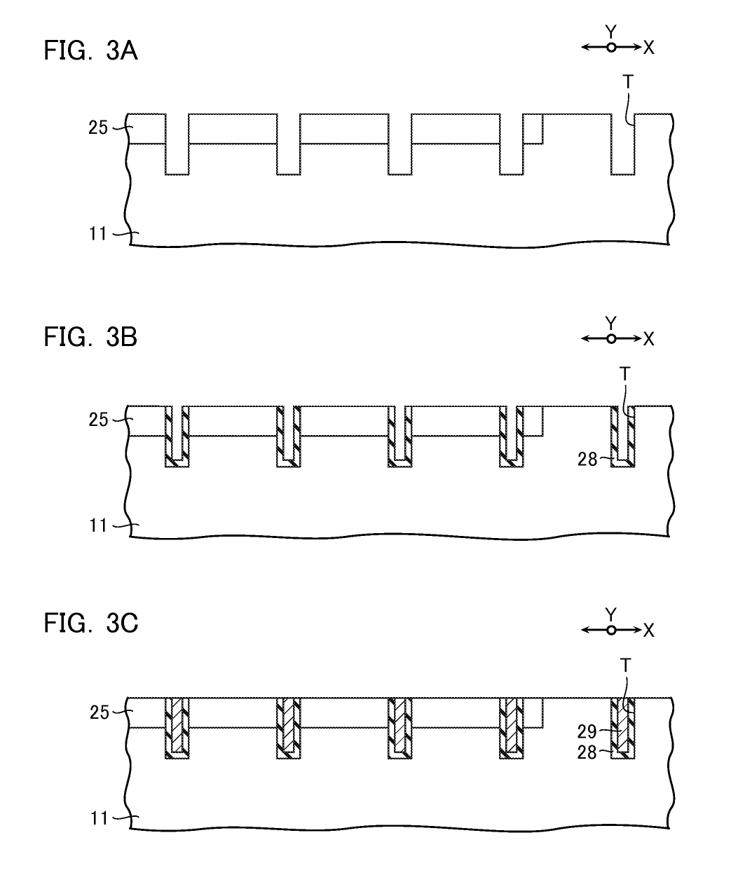

Next, manufacturing processes of the end region 20 according to the embodiment are described with reference to FIGS. 3A-3C. First, as shown in FIG. 3A, the n type semiconductor substrate 11 is etched to form the trench T extending to a certain depth from a surface of the n type semiconductor substrate 11. Next, as shown in FIG. 3B, the insulating layer 28 of a certain thickness is formed on an inner wall of the trench T by a chemical vapor deposition (CVD) method. Then, as shown in FIG. 3C, the field plate conductive layer 29 is formed by CVD so as to fill the trench T.

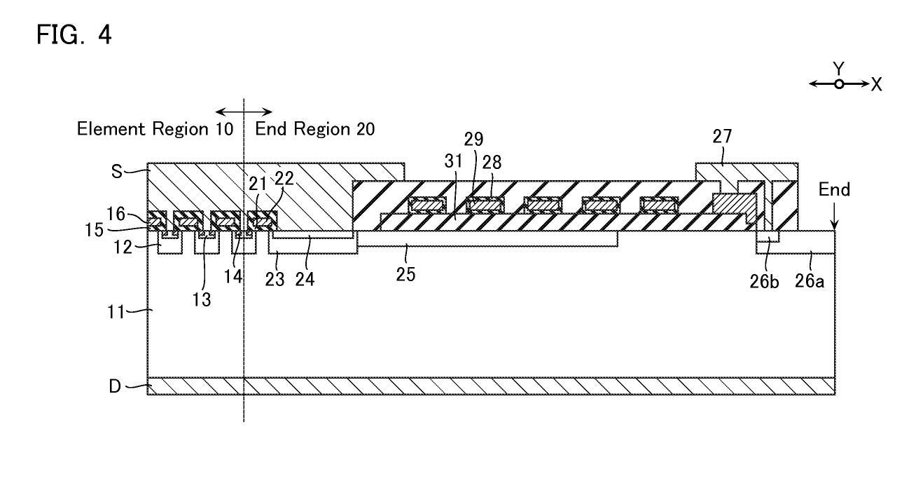

Next, the present embodiment is compared with a comparative example shown in FIG. 4. In the comparative example shown in FIG. 4, a trench T is not formed in the end region 20. Moreover, the insulating layer 28 and the field plate conductive layer 29 in the comparative example are formed on the n type semiconductor substrate 11 via an insulating layer 31. The comparative example differs from the present embodiment only in the above-described points. Even a comparative example of this kind allows electric field to be relieved by the field plate conductive layer 29 similarly to in the present embodiment.

However, in the comparative example, after forming a thin film on the insulating layer 31 by CVD, that thin film is processed by etching to form the field plate conductive layer 29. Therefore, because variation occurs in a film thickness and a width of the field plate conductive layer 29 in a manufacturing process, a resistance value of the field plate conductive layer 29 also has variation. This causes variation to occur in behavior of the semiconductor device. Moreover, due to constraints in film thickness of CVD or constraints in processing dimensions of etching and so on, the width of the field plate conductive layer 29 cannot be processed small. That is, in the comparative example, it is difficult to reduce size of the end region 20.

In contrast, as mentioned above, the present embodiment includes the field plate conductive layer 29 within the trench T. Therefore, in the present embodiment, since the field plate conductive layer 29 has a structure which is not reliant on control of film thickness due to CVD, variation in resistance value of the field plate conductive layer 29 is small compared to in the comparative example. Thereby, behavior of the semiconductor device in the present embodiment can be more greatly stabilized than in the comparative example. Moreover, the present embodiment is never subject to constraints in film thickness or constraints in processing dimensions as in the comparative example, hence the width of the field plate conductive layer 29 can be made smaller than in the comparative example. That is, size of the end region 20 in the present embodiment can be made smaller than in the comparative example.

[Other]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the element region 10 may be provided with an IGBT or the like, in addition to the MOSFET.

What is claimed is:

1. A semiconductor device comprising an element region and an end region, the element region having a semiconductor element formed therein, and the end region surrounding the element region, the semiconductor device comprising:
a semiconductor substrate;
a trench formed in the semiconductor substrate so as to surround the element region in the end region; and
a field plate conductive layer formed in the trench via an insulating layer,
the insulating layer being configured by silicon oxide (SiO₂),
the field plate conductive layer being configured by any of polysilicon and a metal material,
a width of the trench being 0.4 μm˜2.0 μm, and
a depth of the trench being 2 μm˜6 μm.

2. A semiconductor device including an element region and an end region, the element region having a semiconductor element formed therein, and the end region surrounding the element region, the semiconductor device comprising:
a semiconductor substrate;
a trench formed in the semiconductor substrate so as to surround the element region in the end region; and
a field plate conductive layer formed in the trench via an insulating layer.

3. The semiconductor device according to claim 2, wherein
the insulating layer is configured by silicon oxide (SiO₂).

4. The semiconductor device according to claim 3, wherein
the field plate conductive layer is configured by any of polysilicon and a metal material.

5. The semiconductor device according to claim 2, wherein
a width of the trench is 0.4 μm˜2.0 μm.

6. The semiconductor device according to claim 2, wherein
a depth of the trench is 2 μm˜6 μm.

7. The semiconductor device according to claim 2, wherein
the trench and the field plate conductive layer are formed spirally surrounding the element region.

8. The semiconductor device according to claim 2, wherein
the trench and the field plate conductive layer are formed concentrically surrounding the element region.

9. The semiconductor device according to claim 2, wherein
a MOSFET is formed in the element region.

10. The semiconductor device according to claim 2, wherein
an IGBT is formed in the element region.

11. The semiconductor device according to claim 2, wherein
the semiconductor substrate is a semiconductor substrate of a first conductivity type, and
the semiconductor device further comprises:
a base layer of a second conductivity type, the base layer being formed in a surface of the semiconductor substrate in the element region;
a contact layer of the second conductivity type, the contact layer being formed in a surface of the base layer in the element region and having an impurity concentration which is higher than that of the base layer;
a source diffusion layer of the first conductivity type, the source diffusion layer being formed in a surface of the contact layer in the element region; and
a gate electrode formed on the semiconductor substrate via a gate insulating film in the element region.

12. The semiconductor device according to claim 2, wherein
the semiconductor substrate is a semiconductor substrate of a first conductivity type,
the semiconductor device further comprises:
a first guard ring layer of a second conductivity type, the first guard ring layer being formed in a surface of the semiconductor substrate in the end region;
a second guard ring layer of the second conductivity type, the second guard ring layer being formed in a surface of the first guard ring layer in the end region and having an impurity concentration which is higher than that of the first guard ring layer; and
a third guard ring layer of the second conductivity type, the third guard ring layer being formed in the surface of the semiconductor substrate in the end region, being adjacent to the first guard ring layer and the second guard ring layer, and having an impurity concentration which is lower than that of the first guard ring layer, and
the first guard ring layer, the second guard ring layer, and the third guard ring layer are formed circularly surrounding the element region.

13. The semiconductor device according to claim 2, wherein
the semiconductor substrate is a semiconductor substrate of a first conductivity type,
the semiconductor device further comprises:
a first field stop layer of a second conductivity type, the first field stop layer being formed in a surface of the semiconductor substrate in the end region; and
a second field stop layer of the first conductivity type, the second field stop layer being formed in a surface of the first field stop layer in the end region, and
the first field stop layer and the second field stop layer are provided at an end of the semiconductor substrate.

14. A method of manufacturing a semiconductor device, the semiconductor device including an element region and an end region, the element region having a semiconductor element formed therein, and the end region surrounding the element region, the method comprising:
forming a trench in a semiconductor substrate such that the trench surrounds the element region in the end region;
forming an insulating layer on an inner wall of the trench; and
forming a field plate conductive layer in the trench via the insulating layer.

15. The method of manufacturing a semiconductor device according to claim 14, wherein
the insulating layer is configured by silicon oxide (SiO₂).

16. The method of manufacturing a semiconductor device according to claim 14, wherein
the field plate conductive layer is configured by any of polysilicon and a metal material.

17. The method of manufacturing a semiconductor device according to claim 14, wherein
a width of the trench is 0.4 μm˜2.0 μm.

18. The method of manufacturing a semiconductor device according to claim 14, wherein
a depth of the trench is 2 μm˜6 μm.

19. The method of manufacturing a semiconductor device according to claim 14, wherein
the trench and the field plate conductive layer are formed spirally surrounding the element region.

20. The method of manufacturing a semiconductor device according to claim 14, wherein
the trench and the field plate conductive layer are formed concentrically surrounding the element region.
